(19) United States
(12) Patent Application Publication
(10) Pub. No.: US 2010/0300526 A1
(43) Pub. Date: Dec. 2, 2010

(54) SOLAR CELL AND METHOD FOR MANUFACTURING SOLAR CELL

(75) Inventors: Atsushi DENDA, Chino (JP); Hiromi SAITO, Chino (JP)

Correspondence Address: GLOBAL IP COUNSELORS, LLP, 1233 20TH STREET, NW, SUITE 700, WASHINGTON, DC, 20036-2680, US

(73) Assignee: SEIKO EPSON CORPORATION, Tokyo (JP)

(21) Appl. No.: 12/789,089

(22) Filed: May 27, 2010

(30) Foreign Application Priority Data
Jun. 2, 2009 (JP) 2009-132840

(51) Int. Cl. H01L 31/0224; H01L 31/18

(52) U.S. Cl. 136/256; 438/98; 257/E31.124

(57) ABSTRACT

A solar cell includes a substrate, a first electrode layer formed on the substrate, a semiconductor layer formed on the first electrode layer, a second electrode layer formed on the semiconductor layer, and a conductive contact layer formed in a groove portion extending from the first electrode layer to the second electrode layer in a portion of the semiconductor layer.

### CROSS-REFERENCE TO RELATED APPLICATIONS

This application claims priority to Japanese Patent Application No. 2009-132840 filed on Jun. 2, 2009. The entire disclosure of Japanese Patent Application No. 2009-132840 is hereby incorporated herein by reference.

### BACKGROUND

1. Technical Field

The present invention relates to a solar cell and to a method for manufacturing a solar cell.

2. Related Art

A solar cell converts light energy into electrical energy, and various types of configurations of solar batteries have been proposed according to the semiconductor used. In recent years, CIGS-type solar batteries have been emphasized for the simple manufacturing process thereof and the ability to realize high conversion efficiency. A CIGS solar cell is composed, for example, of a first electrode film formed on a substrate, a thin film that includes a compound semiconductor (copper-indium-gallium-selenide) formed on the first electrode film, and a second electrode film that is formed on the thin film. The second electrode film is formed in a groove formed by removing a portion of the thin film, and the first electrode film and second electrode film are electrically connected (see Japanese Laid-Open Patent Publication No. 2002-319686, for example).

### SUMMARY

The groove in the abovementioned thin film (compound semiconductor layer) is formed by removing a portion of the thin film using laser irradiation, a metal needle, or the like. When a residue of the thin film adheres to the inside of the groove formed as described above, the fact that the thin film residue has high resistance results in high electrical resistance between the first electrode film and the second electrode film when the second electrode film is formed in the groove, and the first electrode film and second electrode film are connected.

The present invention was developed in order to overcome at least some of the problems described above, and the present invention can be implemented in the form of the embodiments or applications described below.

A solar cell according to a first aspect includes a substrate, a first electrode layer formed on the substrate, a semiconductor layer formed on the first electrode layer, a second electrode layer formed on the semiconductor layer, and a conductive contact layer formed in a groove portion extending from the first electrode layer to the second electrode layer in a portion of the semiconductor layer.

According to this configuration, the first electrode layer and the second electrode layer are electrically connected by the contact layer formed in the groove portion of the semiconductor layer. The electrical connection between the first electrode layer and the second electrode layer can therefore be easily ensured.

In the solar cell as described above, the contact layer preferably includes a material having lower electrical resistivity than the first electrode layer and the second electrode layer.

According to this configuration, since the contact layer has lower electrical resistivity than the first electrode layer and the second electrode layer, the electrical resistance between the first electrode layer and the second electrode layer can be reduced.

In the solar cell as described above, the contact layer preferably includes a material having copper as a primary component.

According to this configuration, since the contact layer is formed by a material having low specific resistance, the resistance between the first electrode layer and the second electrode layer can be reduced.

In the solar cell as described above, the semiconductor layer preferably has a compound semiconductor layer comprising copper, indium, gallium, and selenium, and the contact layer is preferably formed by heat treatment.

According to this configuration, the semiconductor layer has a compound semiconductor layer that includes copper, indium, gallium, and selenium (CIGS), and the contact layer is a material primarily composed of copper. In this arrangement, when a portion of the compound semiconductor layer is removed to form a groove portion using laser irradiation, a metal needle, or the like, for example, a residue of the compound semiconductor layer may adhere to the inside of the groove portion. Therefore, by using a material primarily composed of copper in the groove portion and forming the contact layer by a heat treatment, the residue can be diffused in the copper contact layer during the heat treatment. The electrical resistance between the first electrode layer and the second electrode layer can thereby be reduced. In particular, the interface resistance between the first electrode layer and the contact layer can be reduced.

In the solar cell as described above, the contact layer is preferably formed in the groove portion to be flush with a surface of the semiconductor layer facing the second electrode layer.

According to this configuration, the surfaces of the contact layer and the semiconductor layer are uniform with respect to each other. Specifically, there is no level difference between the surfaces of the semiconductor layer and the contact layer. Since the contact layer and the second electrode layer are therefore connected by a single flat surface, the connection properties between the contact layer and the second electrode layer can be enhanced.

A method for manufacturing a solar cell includes forming a first electrode layer on a substrate; forming a semiconductor layer on the first electrode layer; removing a portion of the semiconductor layer in a thickness direction and forming a groove portion extending to the first electrode layer; forming a conductive contact layer in the groove portion; and forming a second electrode layer on the semiconductor layer and the contact layer.

According to this configuration, the first electrode layer and the second electrode layer are electrically connected by the contact layer formed in the groove portion of the semiconductor layer. The electrical connection between the first electrode layer and the second electrode layer can therefore be easily ensured.

### BRIEF DESCRIPTION OF THE DRAWINGS

Referring now to the attached drawings which form a part of this original disclosure:

FIG. 1 is a view showing the structure of the solar cell;

FIG. 2 is a process view showing the method for manufacturing a solar cell;

FIG. 3 is a process view showing the method for manufacturing a solar cell; and

FIG. 4 is a view showing the structure of the solar cell according to a modification.

### DETAILED DESCRIPTION OF EXEMPLARY EMBODIMENTS

Specific embodiments of the present invention will be described hereinafter with reference to the drawings. Each of the members shown in the drawings is shown sufficiently large to recognize, and members are not shown to scale in relation to each other.

### Structure of Solar Cell

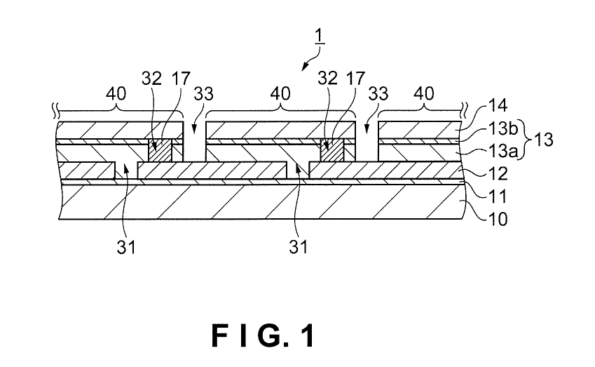

The structure of the solar cell (solar battery) will first be described. In the present embodiment, the structure of a CIGS-type solar cell will be described. FIG. 1 is a sectional view showing the structure of the solar cell according to the present embodiment.

As shown in FIG. 1, the solar cell 1 is composed of an aggregate of cells 40 that are composed of a substrate 10; a base layer 11 formed on the substrate 10; a first electrode layer 12 formed on the base layer 11; a semiconductor layer 13 formed on the first electrode layer 12; a second electrode layer 14 formed on the semiconductor layer 13; and contact layers 17 for electrically connecting the first electrode layer 12 and the second electrode layer 14.

Adjacent cells 40 are divided from each other by third separating grooves 33. The first electrode layer 12 is divided into cell 40 units by first dividing grooves 31, and is formed so as to bridge the spaces between adjacent cells 40. The contact layers 17 are formed in second dividing grooves 32 as groove portions provided in portions of the semiconductor layer 13, and the first electrode layer 12 and second electrode layer 14 are connected via the contact layers 17. The second electrode layer 14 of the cells 40 is connected to the first electrode layer 12 of the other adjacent cells 40, whereby the cells 40 are each connected in series. The desired voltage in the solar cell 1 can thus be designed and changed to any value by appropriately setting the number of cells 40 that are connected in series.

The substrate 10 is a substrate in which at least the surface thereof on the side of the first electrode layer 12 has insulating properties. Specific examples of substrates that can be used include glass (blue sheet glass or the like) substrates, stainless steel substrates, polyimide substrates, and mica substrates.

The base layer 11 is a layer having insulating properties that is formed on the substrate 10, and an insulation layer primarily composed of SiO₂ (silicon dioxide), or an iron fluoride layer may be provided. The base layer 11 has insulating properties, and also has the function of maintaining adhesion between the substrate 10 and the first electrode layer 12 formed on the substrate 10, and when the substrate 10 is composed of blue sheet glass, the base layer 11 has the function of preventing Na diffusion from the glass substrate to the first electrode layer 12. The base layer 11 may be omitted when the substrate 10 has the characteristics described above.

The first electrode layer 12 is a conductive layer formed on the base layer 11, and molybdenum (Mo), for example, may be used for the first electrode layer 12.

The semiconductor layer 13 is composed of a first semiconductor layer 13a and a second semiconductor layer 13b. The first semiconductor layer 13a is formed on the first electrode layer 12, and is a p-type semiconductor layer that includes copper (Cu), indium (In), gallium (Ga, and selenium (Se) (CIGS semiconductor layer).

The second semiconductor layer 13b is formed on the first semiconductor layer 13a, and is a cadmium sulfide (CdS), zinc oxide (ZnO), indium sulfide (InS), or other n-type semiconductor layer.

The second electrode layer 14 is a transparent electrode layer formed on the second semiconductor layer 13b, and is composed of AZO (Al-doped zinc oxide) or another transparent electrode (TCO: transparent conducting oxides) or the like, for example.

The contact layers 17 are conductive layers that are formed by a material having lower electrical resistivity than the first electrode layer 12 and the second electrode layer 14. Specifically, copper (Cu) or a material primarily composed of copper is used to form the contact layers 17. The contact layers 17 may also be formed using gold (Au), silver (Ag), a copper-manganese compound, or another material. By thus using a material having low electrical resistivity, the resistance between the first electrode layer 12 and the second electrode layer 14 can be reduced. In the present embodiment, the second dividing grooves 32 are formed in the semiconductor layer 13, and the contact layers 17 are formed in the second dividing grooves 32. The contact layers 17 are more preferably formed so as to have the same height as the surface of the semiconductor layer 13 so that surfaces of the contact layers 17 are substantially flush with the surface of the semiconductor layer 13. In other words, the top surface of the semiconductor layer 13 and the top surfaces of the contact layers 17 preferably form a single flat surface, and the second electrode layer 14 is formed on the flat surface.

When sunlight or other light is incident on the CIGS-type solar cell 1 configured as described above, electrons (−) and positive holes (+) occur in pairs in the semiconductor layer 13, and the electrons (−) collect in the n-type semiconductor, and the positive holes (+) collect in the p-type semiconductor at the joint surface between the p-type semiconductor layer (first semiconductor layer 13a) and the n-type semiconductor layer (second semiconductor layer 13b). As a result, an electromotive force arises between the n-type semiconductor layer and the p-type semiconductor layer. In this state, a current can be directed to the outside by connecting an external conductor to the first electrode layer 12 and the second electrode layer 14.

### Method for Manufacturing Solar Cell

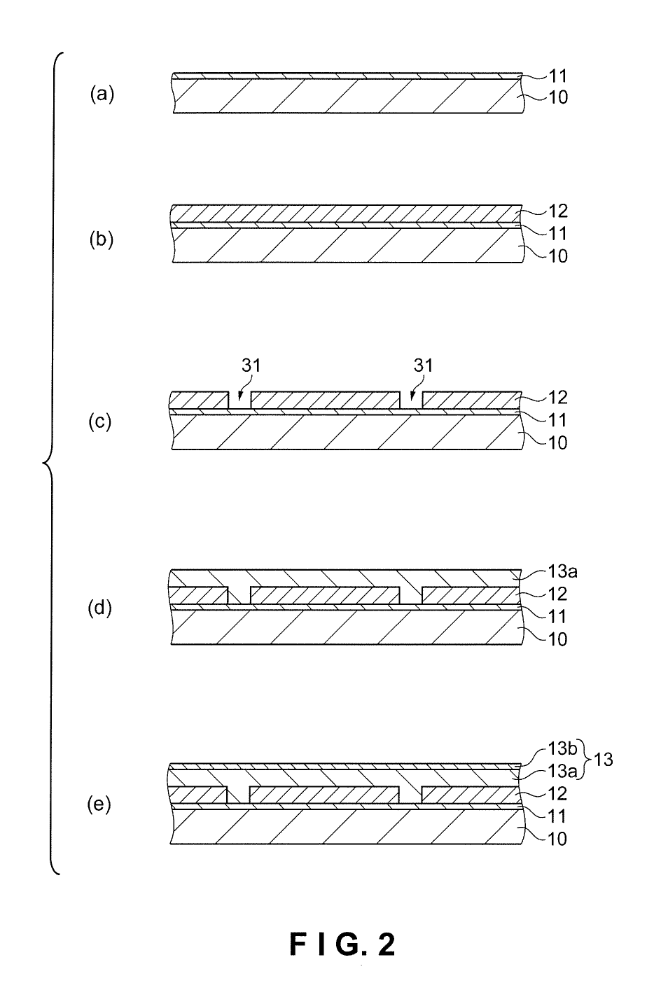

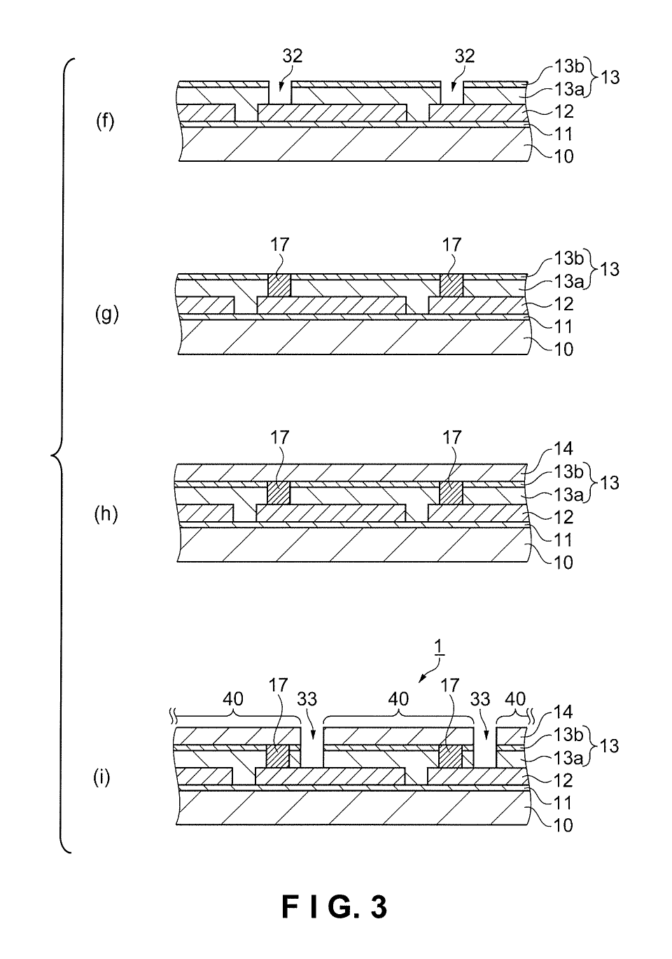

The method for manufacturing the solar cell will next be described. In the present embodiment, a method for manufacturing a CIGS-type solar cell will be described. FIGS. 2 and 3 are process views showing the method for manufacturing a solar cell according to the present embodiment.

In a base layer formation step shown in FIG. 2(a), the base layer 11 is formed on one surface of a stainless steel substrate 10. The base layer 11 composed of iron fluoride can be formed by reacting the stainless steel substrate 10 with a fluorine-containing gas. The base layer 11 maintains insulation properties and also has the effect of increasing adhesion between the first electrode layer 12 and the substrate 10. The base layer formation step may be omitted when the substrate 10 as such has the effects of the base layer described above.

In a first electrode layer formation step shown in FIG. 2(b), the first electrode layer 12 is formed on the base layer 11. Specifically, a molybdenum (Mo) layer to act as the first electrode layer 12 is formed by sputtering.

In a first division step shown in FIG. 2(c), a portion of the first electrode layer 12 is removed by laser irradiation or another method, and the first electrode layer 12 is divided in the thickness direction. The first dividing grooves 31 are formed where the first electrode layer 12 was partially removed by laser irradiation or another method.

In a first semiconductor layer formation step shown in FIG. 2(d), copper (Cu), indium (In) and gallium (Ga) are deposited on the first electrode layer 12 and in the first dividing grooves 31 by sputtering, and a precursor is formed. The precursor is then heated (selenized) in a hydrogen selenide atmosphere, and a p-type semiconductor layer (CIGS) is formed to act as the first semiconductor layer 13a.

In a second semiconductor layer formation step shown in FIG. 2(e), an n-type semiconductor layer to act as the second semiconductor layer 13b is formed by CdS, ZnO, InS, or the like on the first semiconductor layer 13a. The second semiconductor layer 13b can be formed by sputtering.

In a groove portion formation step (second division step) shown in FIG. 3(f), a portion of the semiconductor layer 13 is removed by laser irradiation, a metal needle, or another method, and the semiconductor layer 13 is divided in the thickness direction. The second dividing grooves 32 as groove portions are formed where the semiconductor layer 13 was partially removed by laser irradiation or another method.

In a contact layer formation step shown in FIG. 3(g), the contact layers 17 are formed in the second dividing grooves 32. A material having lower electrical resistivity than the first electrode layer 12 and the second electrode layer 14 is used to form the contact layers 17. Specifically, a material primarily composed of copper is used. A material primarily composed of copper is applied in the second dividing grooves 32 by a printing method, an inkjet method, or another method, and baked by heat treatment or the like in nitrogen or an inert gas atmosphere of argon or the like, or in a reducing gas atmosphere in which hydrogen, formic acid, or another reducing component is mixed with the aforementioned inert gas. The contact layers 17 can thereby be formed. The contact layers 17 are also preferably formed so as to have the same height as the bottom surface of the semiconductor layer 13 in the direction of the second electrode layer 14. When the contact layers 17 have the same height as the bottom surface of the semiconductor layer 13 in the direction of the second electrode layer 14, the surfaces of the semiconductor layer 13 and the contact layers 17 form a flat surface that is devoid of level differences.

In an upper electrode layer formation step shown in FIG. 3(h), the second electrode layer 14 is formed on the semiconductor layer 13 and the contact layers 17. For example, an AZO (Al-doped zinc oxide) or other transparent electrode (TCO) to act as the second electrode layer is formed by sputtering or another method.

In a third division step shown in FIG. 3(i), portions of the second electrode layer 14 and semiconductor layer 13 are removed by laser irradiation, a metal needle, or another method, and the second electrode layer 14 and semiconductor layer 13 are divided in the thickness direction. The third separating grooves 33 are formed where the second electrode layer 14 and semiconductor layer 13 were partially removed by laser irradiation or another method, and individual cells 40 are formed.

By the process described above, a CIGS-type solar cell 1 is formed in which a plurality of cells 40 is connected in series.

The effects described below are obtained through the embodiment described above.

(1) The contact layers 17 are formed in the second dividing grooves 32 as groove portions, and the first electrode layer 12 and the second electrode layer 14 are connected via the contact layers 17. The contact layers are formed using a material primarily composed of copper, which has low electrical resistivity. The resistance between the first electrode layer 12 and the second electrode layer 14 can thereby be reduced.

(2) The contact layers 17 are formed so as to have the same height as the semiconductor layer 13. Connection properties can thereby be enhanced, because there are no level differences between the connecting surfaces of the contact layers 17 and the second electrode layer 14.

(3) After the groove portion formation (second division formation) step, copper to act as the contact layers 17 is applied in the second dividing grooves 32, and the contact layers 17 are formed by heat treatment. Even when residue of the first semiconductor layer 13a (CIGS) adheres in the second dividing grooves 32, since the residue is diffused in the copper in the groove portion formation (second division formation) step, the interface resistance at the connection interfaces between the first electrode layer 12 and the contact layers 17 can be reduced.

The present invention is not limited to the embodiments described above, and may include such modifications as those described below.

### Modification 1

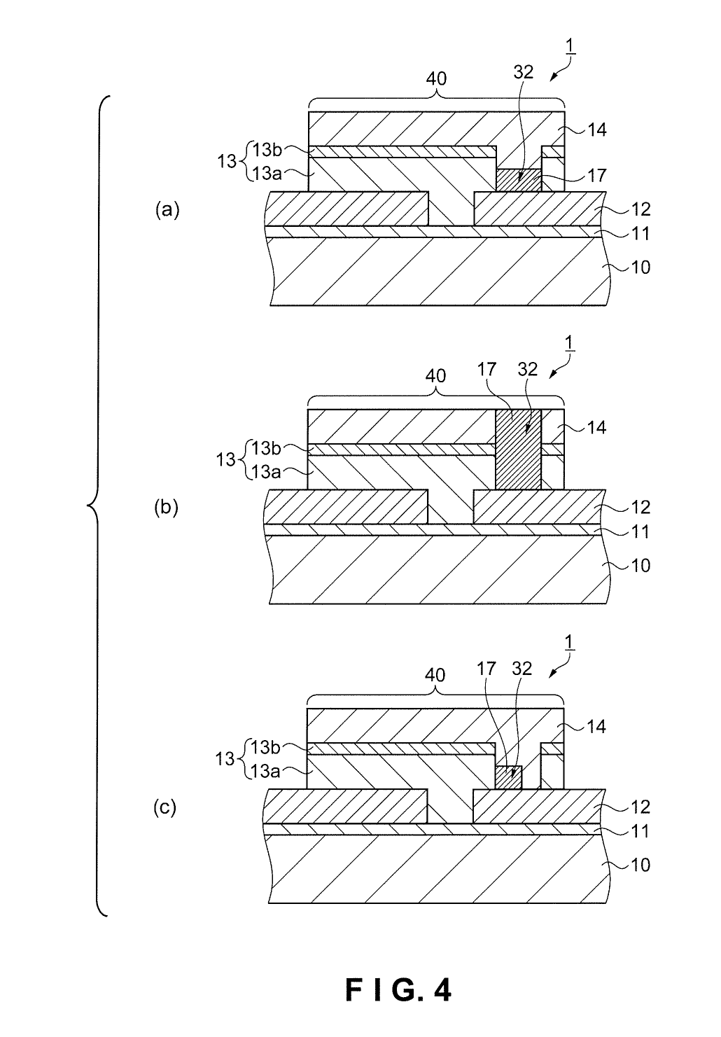

In the embodiment described above, the contact layers 17 are formed so as to fill the insides of the second dividing grooves 32, and so as to have the same height as the surface of the semiconductor layer 13, but this configuration is not limiting. For example, the contact layers 17 may be formed so that the surfaces thereof are lower than the surface of the semiconductor layer 13, as shown in FIG. 4(a), or the contact layers 17 may be formed so that the surfaces thereof are higher than the surface of the semiconductor layer 13, as shown in FIG. 4(b). The contact layers 17 may also be provided in a portion of the insides of the second dividing grooves 32, as shown in FIG. 4(c). The resistance between the first electrode layer 12 and the second electrode layer 14 can be reduced through this configuration as well.

### Modification 2

In the embodiment described above, a description is provided of the structure and other aspects of a one-sided CIGS-type solar cell 1 for receiving light from the side of the second electrode layer 14, but the solar cell 1 may also be a double-sided CIGS-type solar cell 1 that is capable of receiving light from the side of the substrate 10 as well as from the side of the second electrode layer 14. In this case, a transparent substrate is used as the substrate 10. For example, a glass substrate, a PET substrate, an organic transparent substrate, or the like may be used. The first electrode layer 12 is a transparent electrode layer, and is an AZO (Al-doped zinc oxide) or other transparent electrode (TCO: transparent conducting oxides) layer, for example. By using a transparent substrate 10 and using a transparent electrode as the first electrode layer 12, light that is incident from the substrate 10 side can pass through the first electrode layer 12 to reach the semiconductor layer 13 and contribute to photoelectric conversion. In the double-sided CIGS-type solar cell 1 described above, the first electrode layer 12 and the second electrode layer 14 are electrically connected via the contact layers 17, and the series resistance between the electrodes can thereby be reduced.

### Modification 3

In the embodiment described above, the contact layers 17 are described as being applied to a CIGS-type solar cell, but this configuration is not limiting. For example, the contact layers 17 may be applied to the electrode connection structure in a thin-film silicon solar cell. The series resistance between electrodes can be reduced in this case as well.

### General Interpretation of Terms

In understanding the scope of the present invention, the term “comprising” and its derivatives, as used herein, are intended to be open ended terms that specify the presence of the stated features, elements, components, groups, integers, and/or steps, but do not exclude the presence of other unstated features, elements, components, groups, integers and/or steps. The foregoing also applies to words having similar meanings such as the terms, “including”, “having” and their derivatives. Also, the terms “part,” “section,” “portion,” “member” or “element” when used in the singular can have the dual meaning of a single part or a plurality of parts. Finally, terms of degree such as “substantially”, “about” and “approximately” as used herein mean a reasonable amount of deviation of the modified term such that the end result is not significantly changed. For example, these terms can be construed as including a deviation of at least ±5% of the modified term if this deviation would not negate the meaning of the word it modifies.

While only selected embodiments have been chosen to illustrate the present invention, it will be apparent to those skilled in the art from this disclosure that various changes and modifications can be made herein without departing from the scope of the invention as defined in the appended claims. Furthermore, the foregoing descriptions of the embodiments according to the present invention are provided for illustration only, and not for the purpose of limiting the invention as defined by the appended claims and their equivalents.

What is claimed is:

1. A solar cell comprising:
a substrate;
a first electrode layer formed on the substrate;
a semiconductor layer formed on the first electrode layer;
a second electrode layer faulted on the semiconductor layer; and
a conductive contact layer formed in a groove portion extending from the first electrode layer to the second electrode layer in a portion of the semiconductor layer.

2. The solar cell according to claim 1, wherein
the contact layer includes a material having lower electrical resistivity than the first electrode layer and the second electrode layer.

3. The solar cell according to claim 2, wherein
the contact layer includes a material having copper as a primary component.

4. The solar cell according to claim 3, wherein
the semiconductor layer has a compound semiconductor layer including copper, indium, gallium, and selenium, and
the contact layer is formed by heat treatment.

5. The solar cell according to claim 1, wherein
the contact layer is formed in the groove portion so that a surface of the contact layer is substantially flush with a surface of the semiconductor layer facing the second electrode layer.

6. A method for manufacturing a solar cell comprising:
foaming a first electrode layer on a substrate;
forming a semiconductor layer on the first electrode layer;
removing a portion of the semiconductor layer in a thickness direction and forming a groove portion extending to the first electrode layer;
forming a conductive contact layer in the groove portion; and
forming a second electrode layer on the semiconductor layer and the contact layer.
